(19) United States
(12) Patent Application Publication
(10) Pub. No.: US 2018/0011392 A1
(43) Pub. Date: Jan. 11, 2018

(54) COOLING DEVICE, PROJECTION DISPLAY DEVICE, AND COOLING METHOD

(71) Applicant: NEC Display Solutions, Ltd., Tokyo (JP)

(72) Inventor: Motoyasu UTSUNOMIYA, Tokyo (JP)

(21) Appl. No.: 15/543,918

(22) PCT Filed: Jan. 28, 2015
(86) PCT No.: PCT/JP2015/052344

§ 371 Date: Jul. 14, 2017

(51) Int. Cl. G03B 21/16; H05K 7/20; G03B 21/20

(52) U.S. Cl. CPC G03B 21/16; H05K 7/20972; G03B 21/204

(57) ABSTRACT

A cooling device includes a thermally conductive housing member that houses a heat generating body, a first air blower that generates first cooling wind flowing along the housing member through the heat generating body inside the housing member, and a second air blower that generates second cooling wind flowing along the housing member outside the housing member.

### TECHNICAL FIELD

The present invention relates to a device that cools a heat generating body, a projection display device including the same, and a method of cooling a heat generating body.

### BACKGROUND ART

Projection display devices that display video in an enlarged size are widely used in a range from a personal theater to professional presentation. WO2010/018623 (hereinafter referred to as “Patent Literature 1”) discloses an example of such a projection display device.

A projection display device disclosed in Patent Literature 1 is provided with an optical engine including optical components such as a laser light source and a color wheel. The laser light source has a lifetime longer than that of an ultrahigh-pressure mercury lamp, which is an advantage. It is necessary to increase the lifetime of the optical engine is required to be increased to exploit this advantage of the laser light source.

To increase the lifetime of the optical engine, each optical component needs to be cooled to have an operation temperature within a required specification, and the optical engine needs to have a sealed structure to reduce performance degradation of the optical components dust. For this reason, it is disclosed that the projection display device includes a cooling device configured to cool a heat generating body housed in a sealed housing member.

The following describes a cooling device related to the present invention with reference to FIGS. 1 and 2.

FIG. 1 is a schematic cross-sectional view illustrating an exemplary cooling device. A cooling device 1 illustrated in FIG. 1 includes sealed housing member 2, heat transferring mean 3, heat radiator 4, and air blower 5. Housing member 2 houses heat generating body 6. Heat radiator 4 and air blower 5 are disposed outside housing member 2.

Heat transferring means 3 includes heat receiving part 3a inside housing member 2, and heat radiating part 3b outside housing member 2. Heat receiving part 3a is connected to heat generating body 6 to transfer heat radiated from heat generating body 6 to the outside of housing member 2 through heat transferring means 3. Heat radiating part 3b is connected to heat radiator 4. Heat is radiated from heat radiator 4 when air blower 5 blows cooling wind to heat radiator 4.

FIG. 2 is a schematic cross-sectional view illustrating another exemplary cooling device. Any component identical to that of cooling device 1 illustrated in FIG. 1 is denoted by an identical reference sign, and description thereof will be omitted. Cooling device 7 illustrated in FIG. 2 further includes heat absorber 8 and air blower 9 separated from air blower 5. Housing member 2 houses a plurality of heat generating bodies 6, heat absorber 8, and air blower 9. Heat absorber 8 is connected with heat transferring means 3.

Air blower 9 generates cooling wind (circulation cooling wind) circulating inside housing member 2. Heat generating bodies 6 are disposed on the path of the circulation cooling wind generated by air blower 9, and are air-cooled by air blower 9. Heat absorber 8 is disposed on the path of the circulation cooling wind. Heat transferred from heat generating bodies 6 to the circulation cooling wind is radiated to the outside of housing member 2 through heat absorber 8 and heat transferring means 3.

In this manner, heat inside housing member 2 is radiated to the outside of housing member 2 by cooling devices 1 and 7 (refer to FIGS. 1 and 2), so that any increase in the temperature inside housing member 2 can be reduced. Accordingly, heat generating body 6 housed in housing member 2 can be cooled more efficiently.

### CITATION LIST

### Patent Literature

### Patent Literature 1: WO2010/018623

### SUMMARY OF INVENTION

### Technical Problem

In cooling device 1 illustrated in FIG. 1, heat generating body 6 needs to be connected with heat receiving part 3a. Thus, when cooling device 1 includes a plurality of heat generating bodies 6, heat receiving part 3a needs to be connected with all heat generating bodies 6, which is likely to lead to a complicated structure of heat transferring means 3.

In cooling device 7 illustrated in FIG. 2, the heat of the circulation cooling wind is radiated to the outside of housing member 2 by exploiting heat transfer between fluid and solid states. Heat absorber 8 needs to have a sufficiently large heat-transfer area because the efficiency of heat transfer is relatively small. This requires increase in the size of heat absorber 8, which results in a larger size of cooling device 7.

Accordingly, the present invention is intended to provide a cooling device, a projection display device, and a cooling method capable of cooling, with a smaller and simpler structure, a heat generating body housed in a housing member.

### Solution to Problem

A cooling device according to the present invention includes a thermally conductive housing member that houses a heat generating body, a first air blower that generates first cooling wind flowing inside the housing member, and a second air blower that generates second cooling wind flowing outside the housing member.

A projection display device according to the present invention includes the cooling device described above. The heat generating body is an optical component.

A cooling method according to the present invention includes housing a heat generating body in a thermally conductive housing member, generating first cooling wind flowing inside the housing member, and generating second cooling wind flowing outside the housing member.

### Advantageous Effect of Invention

The present invention can achieve cooling of, with a smaller and simpler structure, a heat generating body housed in a housing member.

### BRIEF DESCRIPTION OF DRAWINGS

FIG. 1 is a schematic cross-sectional view illustrating an exemplary related cooling device.

FIG. 2 is a schematic cross-sectional view illustrating another exemplary related cooling device.

FIG. 3 is a schematic cross-sectional view of a projection display device to which a cooling device according to the present invention is applicable.

FIG. 4 is a front view of a fluorescent wheel.

FIG. 5 is a front view of a color wheel.

FIG. 6 is a pattern diagram of a projection display device including a cooling device according to a first exemplary embodiment of the present invention.

FIG. 7 is a diagram for describing a co-current heat exchanger.

FIG. 8 is a graph illustrating temperature distributions of high-temperature fluid and low-temperature fluid in the co-current heat exchanger.

FIG. 9 is a diagram for describing a counter-current heat exchanger.

FIG. 10 is a graph illustrating temperature distributions of high-temperature fluid and low-temperature fluid in the counter-current heat exchanger.

FIG. 11 is a pattern diagram illustrating the cooling device according to a second exemplary embodiment of the present invention.

FIG. 12 is a pattern diagram illustrating the cooling device according to a third exemplary embodiment of the present invention.

FIG. 13 is an enlarged pattern diagram illustrating part A in FIG. 12 in detail.

FIG. 14 is an enlarged pattern diagram illustrating part of the cooling device according to a fourth exemplary embodiment of the present invention.

FIG. 15 is an enlarged pattern diagram illustrating part of the cooling device according to a fifth exemplary embodiment of the present invention.

FIG. 16 is an enlarged pattern diagram illustrating part of the cooling device according to a sixth exemplary embodiment of the present invention.

FIG. 17 is an enlarged pattern diagram illustrating part of the cooling device according to a seventh exemplary embodiment of the present invention.

FIG. 18 is an enlarged pattern diagram illustrating part of the cooling device according to an eighth exemplary embodiment of the present invention.

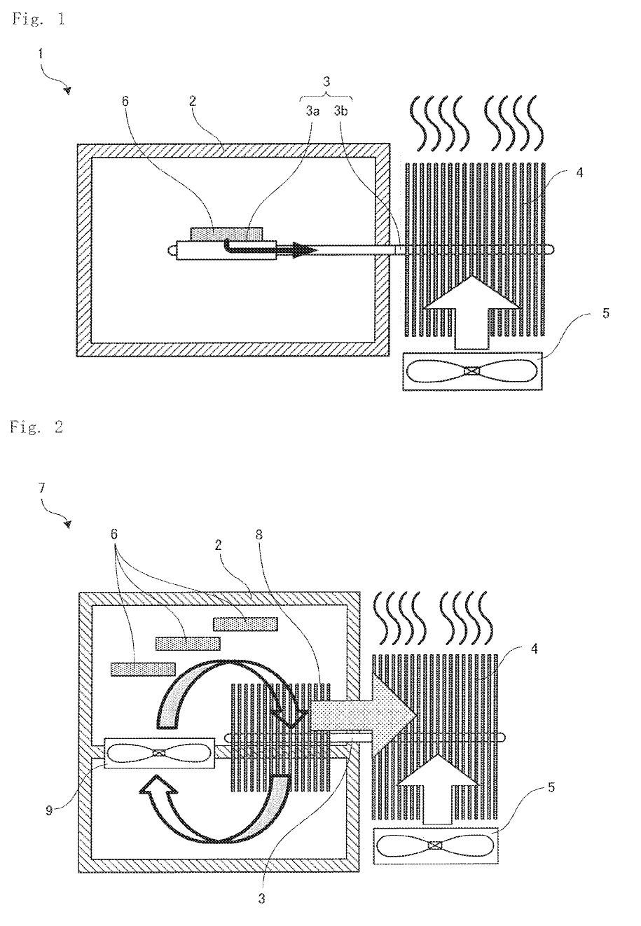

### DESCRIPTION OF EMBODIMENTS

Exemplary embodiments of the present invention will be described below with reference to the accompanying drawings. FIG. 3 is a schematic cross-sectional view of a projection display device to which a cooling device according to the present invention is applicable. As illustrated in FIG. 3, this projection display device 10 includes laser light source 11, fluorescent wheel 12, color wheel 13, light tunnel 14, digital mirror device (DMD) 15, and projection lens 16.

Collimator lens 17, dichroic mirror 18, and light condensing lens 19 are disposed between laser light source 11 and fluorescent wheel 12. Reflection mirror 20 and a light condensing lens 21 are disposed on a side of color wheel 13, which is opposite to light tunnel 14. Light condensing lens 22 is disposed on a side of light tunnel 14, which is opposite to color wheel 13. Total internal reflection (TIR) prism 23 is disposed between DMD 15 and projection lens 16.

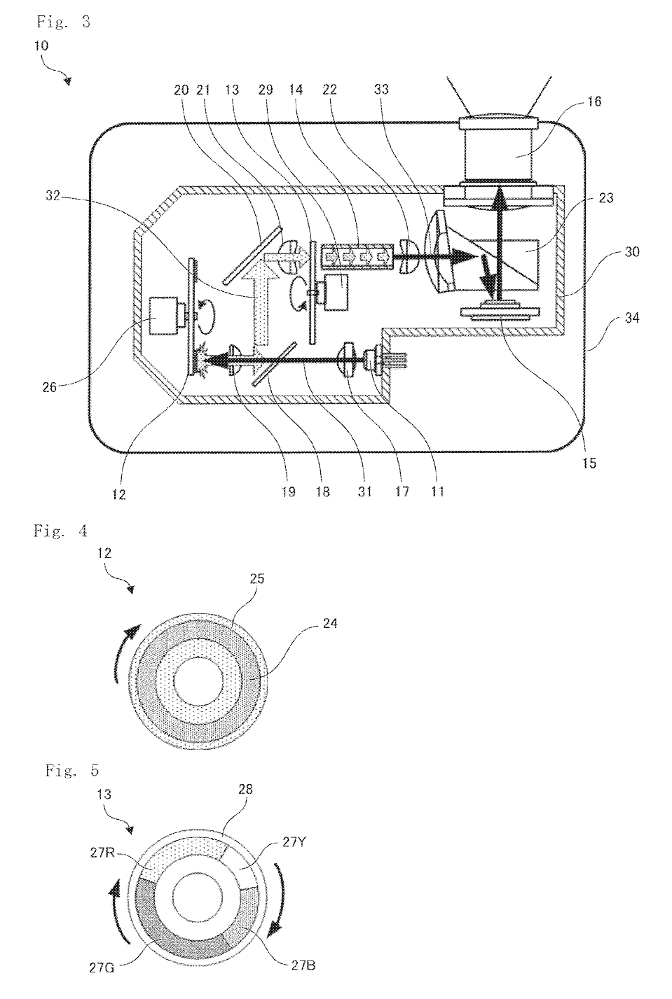

FIG. 4 is a front view of fluorescent wheel 12. As illustrated in FIG. 4, fluorescent wheel 12 includes circular board 25 on which fluorescent member 24 is applied. As illustrated in FIG. 3, fluorescent wheel 12 is coupled with motor 26 and configured to rotate when motor 26 is driven. Fluorescent wheel 12 is rotated to avoid thermal damage on fluorescent member 24 by dispersing the energy of excitation laser light condensed on fluorescent member 24.

FIG. 5 is a front view of color wheel 13. As illustrated in FIG. 5, color wheel 13 includes circular board 28 on which a plurality of color filters 27R, 27G, 27B, and 27Y are disposed in concentric fan shapes. Color filters 27R, 27G, 27B, and 27Y are each coated with a dielectric multi-layered film through evaporation to transmit a predetermined color. As illustrated in FIG. 3, color wheel 13 is coupled with motor 29 and configured to rotate when motor 29 is driven.

Optical components such as fluorescent wheel 12 and color wheel 13 are disposed inside housing member 30 as illustrated in FIG. 3. Housing member 30 is sealed to isolate the inside of housing member 30 from the outside of housing member 30. The integration of the optical components through housing member 30 is also referred to as an “optical engine”. Housing member 30 is also referred to as an “engine block”.

Projection display device 10 further includes a power source, a circuit board, a speaker, an intake fan, and an exhaust fan (all not illustrated). The optical engine, the power source, the circuit board, the speaker, the intake fan, and the exhaust fan are housed in housing 34.

The following describes operation of projection display device 10 with reference to FIGS. 3 to 5.

Laser light 31 emitted from laser light source 11 is incident on fluorescent member 24 on fluorescent wheel 12 through collimator lens 17, dichroic mirror 18, and light condensing lens 19. Fluorescent member 24 is excited by laser light 31 to emit fluorescence (for example, yellow fluorescence) 32 having a wavelength different from that of the excitation light.

Fluorescence 32 is incident on color wheel 13 through light condensing lens 19, dichroic mirror 18, reflection mirror 20, and light condensing lens 21. Incident fluorescence 32 is subjected to time division into color beams (for example, red, green, blue, and yellow beams) in accordance with color segments of color filters 27R, 27G, 27B, and 27Y.

Thereafter, fluorescence 32 passes through light tunnel 14 and is radiated, through light tunnel 14, as a rectangular light beam 33 having uniform illuminance Rectangular light beam 33 is incident on DMD 15 through light condensing lens 22 and total internal reflection prism 23 and modulated in accordance with an image signal. Modulated rectangular light beam 33 is incident on projection lens 16 through total internal reflection prism 23 again, and projected on a screen (not illustrated) in an enlarged size.

In this example, DMD 15 is used as a spatial light modulator, light tunnel 14 is used as a light integrator, and total internal reflection prism 23 is used as a beam separator. However, the present invention is not limited to this configuration. For example, the spatial light modulator may be a liquid crystal panel, the light integrator may be a fly-eye lens, and the beam separator may be a field lens or a mirror.

In addition, in this example, all necessary color beams are generated by using entire laser light 31 to excite fluorescent member 24 and to provide fluorescence 32 emitted from fluorescent member 24 with the time division through color wheel 13. However, the present invention is limited to this configuration. All color beams may be generated in a hybrid scheme when the fluorescence emitted by fluorescent member 24 has a small wavelength component (for example, a blue-light wavelength component).

In the hybrid scheme, part of laser light (for example, blue light) is converted into fluorescence (for example, red light, green light, or yellow light), whereas the remaining laser light is maintained intact. Specifically, all color beams are generated when part of fluorescent member 24 on circular board 25 is cut into a fan shape and replaced with a reflection mirror having the same fan shape so that part of excitation light (for example, blue light) is reflected intact as laser light through the color wheel.

Some components of the optical engine generate heat through light absorption.

For example, fluorescent member 24 of fluorescent wheel 12 described above has an optical conversion efficiency of 50% approximately. Accordingly, when fluorescent member 24 is irradiated with excitation laser light 31, about half of laser light 31 is provided with wavelength conversion and returned onto a light path as fluorescence, while the optical energy of the remaining half of laser light 31 is converted into thermal energy through fluorescent member 24. Thus, fluorescent wheel 12 is a heat generating source.

The optical conversion efficiency of fluorescent member 24 changes depending on the operation temperature. In other words, when the operation temperature of fluorescent member 24 increases, the optical conversion efficiency decreases. When fluorescent wheel 12 is used in a high-luminance projection display device, fluorescent wheel 12 as a heat generating body needs to be cooled to sufficiently provide bright light that is projected onto the screen.

Color wheel 13 never has a transmissivity of 100%, and light tunnel 14 never has a reflectance of 100%. Thus, color wheel 13 and light tunnel 14 absorb part of fluorescence 32 and generate heat. The heat of color wheel 13 and light tunnel 14 damages the motor and adhesive agent and reduces the lifetimes thereof. For this reason, it is necessary to control the operation temperature through an appropriate cooling means.

In addition, for example, light condensing lens 19 for condensing excitation laser light 31 onto fluorescent wheel 12 potentially needs to be cooled to protect coating thereof because light having an extremely high light-beam density passes through light condensing lens 19.

As described above, the optical engine includes a plurality of optical members that need to be cooled.

The following describes a device and a method that cool a heat generating body disposed inside housing member 30, such as fluorescent wheel 12, in more detail in the first to eighth exemplary embodiments. In the following description, the heat generating body is fluorescent wheel 12, but the present invention is not limited thereto. Any heat generating body disposed inside housing member 30 may be a cooling target. Moreover, the same effect can be obtained in a case in which a plurality of heat generating bodies are housed in housing member 30.

### First Exemplary Embodiment

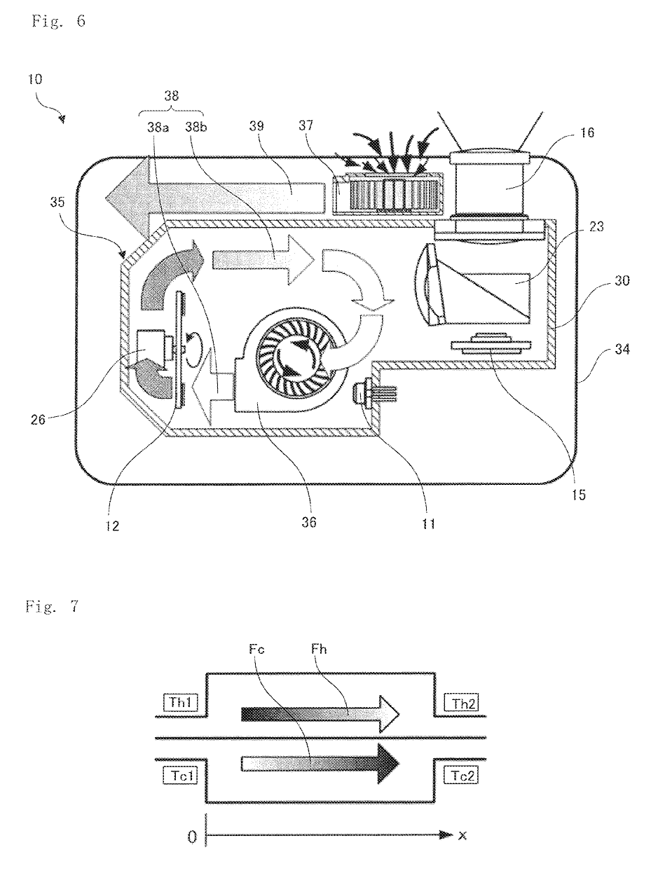

First, the first exemplary embodiment will be described with reference to FIG. 6. FIG. 6 is a pattern diagram of projection display device 10 including a cooling device according to the present exemplary embodiment. As illustrated in FIG. 6, this cooling device 35 includes housing member 30, first air blower 36 positioned inside housing member 30, and second air blower 37 positioned outside housing member 30, and functions as a sealed circulation cooling system. At least part of housing member 30 is made of a thermally conductive material such as aluminum.

First air blower 36 generates, inside housing member 30, first cooling wind 38 that circulates inside housing member 30. Fluorescent wheel 12 is positioned on the path of first cooling wind 38. With this configuration, fluorescent wheel 12 is cooled by first cooling wind 38 (more specifically, low-temperature first cooling wind 38a).

At least part of first cooling wind 38 (high-temperature first cooling wind 38b) having absorbed heat from fluorescent wheel 12 and reached a high temperature flows along an inner wall of housing member 30 and enters into an intake port of first air blower 36. Since housing member 30 is thermally conductive, the heat of high-temperature first cooling wind 38b is transferred to housing member 30 when high-temperature first cooling wind 38b flows along housing member 30. In other words, high-temperature first cooling wind 38b is cooled.

Second air blower 37 generates second cooling wind 39 flowing outside housing member 30. At least part of second cooling wind 39 flows along an outer wall of housing member 30. Accordingly, the heat of housing member 30 is transferred to second cooling wind 39, and housing member 30 is cooled. In other words, the heat of high-temperature first cooling wind 38b is transferred to second cooling wind 39 through housing member 30.

In the present exemplary embodiment, fluorescent wheel 12 does not need to be connected to housing member 30. In addition, there is no need to provide a redundant heat transferring means and no need to connect a heat receiving part of the heat transferring means to fluorescent wheel 12. Thus, when including a plurality of heat generating bodies such as the fluorescent wheels 12, cooling device 35 is still not in a complicated structure.

According to the present exemplary embodiment, heat is exchanged between high-temperature first cooling wind 38b and second cooling wind 39 through housing member 30, which eliminates the need to provide redundant heat absorber 8. This can reduce any increase in the size of cooling device 35.

Second cooling wind 39 preferably flows in a direction opposite to a direction in which high-temperature first cooling wind 38b flows. In this case, cooling device 35 functions as a counter-current heat exchanger.

The following describes a heat exchanger.

A heat exchanger refers to a device that exchanges heat between two fluid bodies. Among such heat exchangers, a plate-separating heat exchanger is a most basic heat exchanger. The plate-separating heat exchanger includes a partition between high-temperature fluid and low-temperature fluid to avoid mixing thereof. Convective heat transfer occurs between the high-temperature fluid and the partition, heat conduction occurs inside the partition, and convective heat transfer occurs between the partition and the low-temperature fluid. Accordingly, heat is transferred from the high-temperature fluid to the low-temperature fluid without causing mixing thereof.

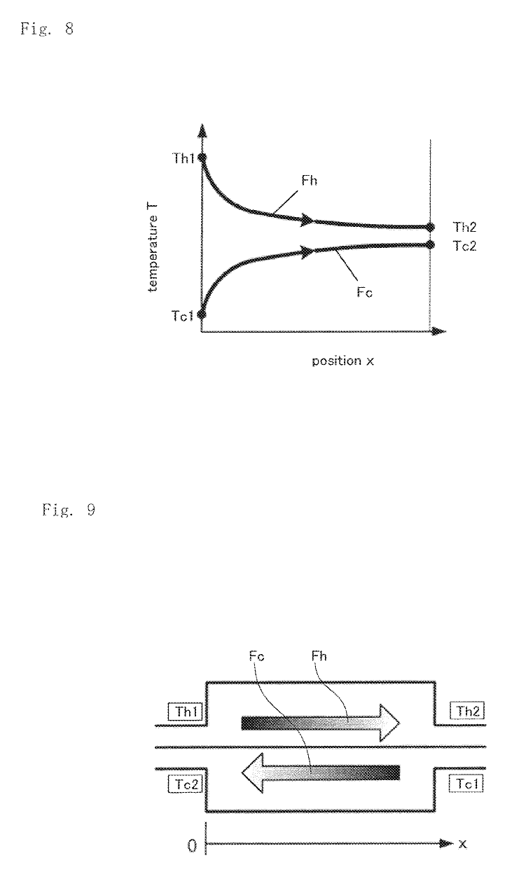

Such plate-separating heat exchangers are categorized depending on flow directions of the high-temperature fluid and the low-temperature fluid. FIG. 7 is a diagram for describing a co-current heat exchanger. As illustrated in FIG. 7, in the co-current heat exchanger, high-temperature fluid Fh and low-temperature fluid Fc flow in the same direction.

FIG. 8 is a graph illustrating temperature distributions of high-temperature fluid Fh and low-temperature fluid Fc in the co-current heat exchanger. In this graph, the horizontal axis represents a position X from an inlet of the co-current heat exchanger, and the vertical axis represents the temperature T of each of high-temperature fluid Fh and low-temperature fluid Fc. As illustrated in FIG. 8, there is a large difference between temperature Th1 of high-temperature fluid Fh and temperature Tc1 of low-temperature fluid Fc near the inlet of the counter-current heat exchanger, and thus heat is efficiently exchanged near the inlet. However, outlet temperature Th2 of high-temperature fluid Fh is never lower than outlet temperature Tc2 of low-temperature fluid Fc.

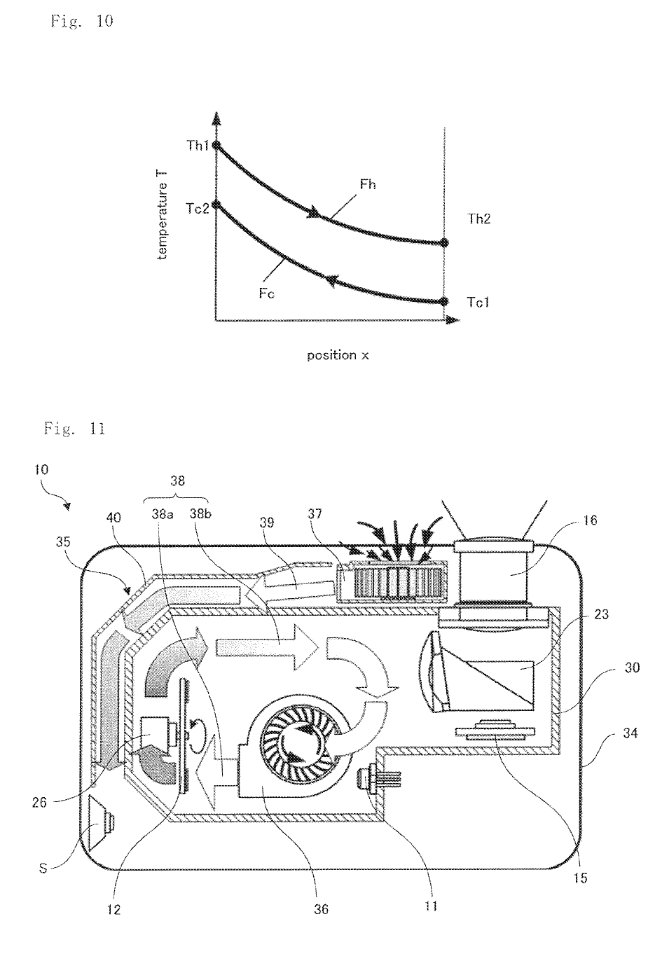

FIG. 9 is a diagram for describing a counter-current heat exchanger. As illustrated in FIG. 9, in the counter-current heat exchanger, high-temperature fluid Fh and low-temperature fluid Fc flow in directions opposite to each other. FIG. 10 is a graph illustrating temperature distributions of high-temperature fluid Fh and low-temperature fluid Fc in the counter-current heat exchanger. In this graph, the horizontal axis represents position X from an inlet of the counter-current heat exchanger for high-temperature fluid Fh, and the vertical axis represents temperature T of each of high-temperature fluid Fh and low-temperature fluid Fc.

As illustrated in FIG. 10, the average temperature difference between high-temperature fluid Fh and low-temperature fluid Fc in the flow direction thereof is maintained relatively large in a large region of the partition as compared to the case of the co-current heat exchanger, thereby achieving improved heat exchange performance. Accordingly, outlet temperature Th2 of high-temperature fluid Fh is lower than outlet temperature Tc2 of low-temperature fluid Fc.

Other examples of plate-separating heat exchangers used in practice include a cross-current heat exchanger and a shell-and-tube heat exchanger. Description thereof will be omitted.

Refer to FIG. 6. A cooling structure according to the present exemplary embodiment is that of a counter-current heat exchanger.

Specifically, while first cooling wind 38 cools a heat generating body (fluorescent wheel 12) and circulates back to an inlet of first air blower 36, second air blower 37 generates second cooling wind 39 flowing in a direction opposite to the circulation direction of first cooling wind 38 (counter current). Accordingly, high-temperature first cooling wind 38b (high-temperature fluid) is cooled to a temperature lower than an outlet temperature (temperature at the end of flow along housing member 30) of second cooling wind 39 (low-temperature fluid). With this configuration, heat inside housing member 30 can be efficiently radiated to the outside of housing member 30, and thus the heat generating body (fluorescent wheel 12) inside housing member 30 can be efficiently cooled while housing member 30 is sealed.

### Second Exemplary Embodiment

The following describes the second exemplary embodiment of the present invention with reference to FIG. 11. FIG. 11 is a pattern diagram illustrating cooling device 35 according to the present exemplary embodiment.

In the present exemplary embodiment, wind guiding plate 40 is disposed outside part of housing member 30, which exchanges heat with high-temperature first cooling wind 38b, in the flow direction of second air blower 37 in the first exemplary embodiment described above. Wind guiding plate 40 guides the flow of second cooling wind 39 so that heat is efficiently exchanged between first cooling wind 38 and second cooling wind 39 across a wider range of housing member 30. With this configuration, the heat radiating performance of the sealed circulation cooling system can be further enhanced.

Wind guiding plate 40 may be used to guide second cooling wind 39 to heat generating bodies such as a power source and a circuit positioned outside housing member 30 and cool these heat generating bodies. FIG. 11 illustrates an example in which second cooling wind 39 is guided to a speaker S as a heat generating body.

### Third Exemplary Embodiment

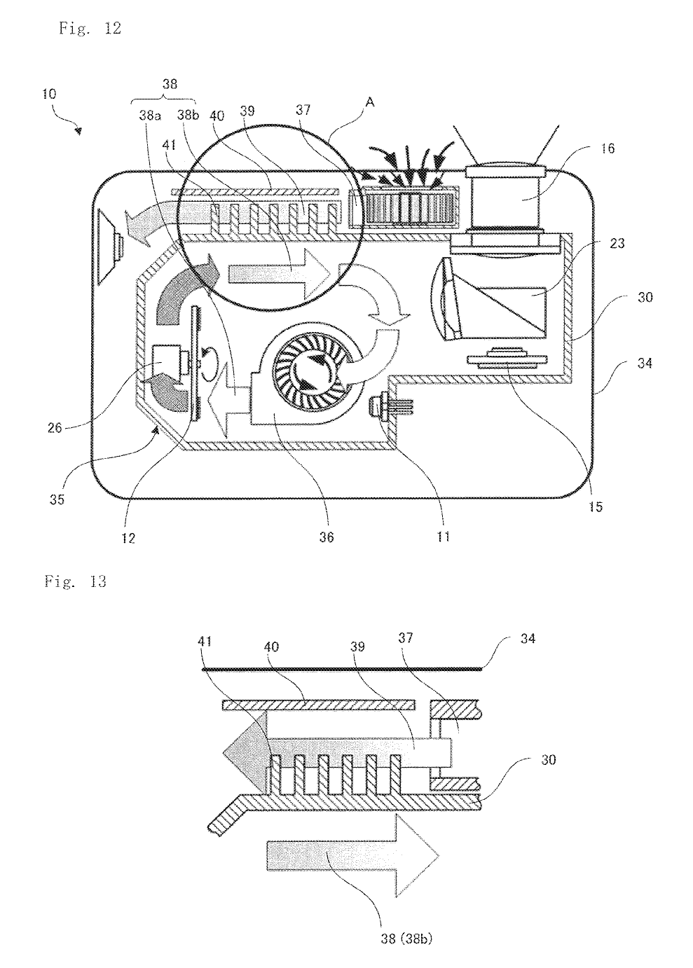

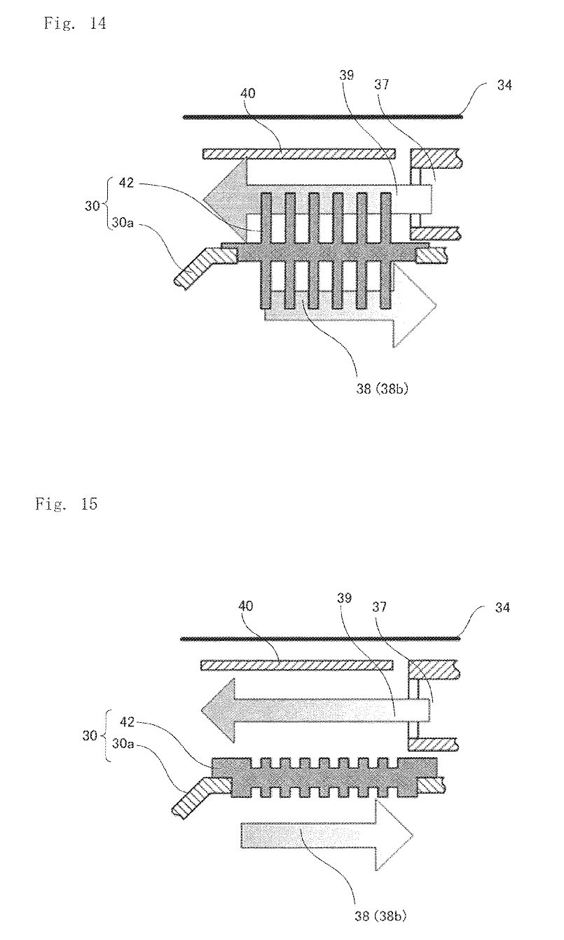

The following describes the third exemplary embodiment of the present invention with reference to FIGS. 12 and 13. FIG. 12 is a pattern diagram illustrating cooling device 35 according to the present exemplary embodiment, and FIG. 13 is an enlarged pattern diagram illustrating part A in FIG. 12 in detail.

In the present exemplary embodiment, heat sink 41 for heat radiation is provided at part of housing member 30, which exchanges heat with first cooling wind 38 in the first or second exemplary embodiment. Although each fin in heat sink 41 extends in a direction perpendicular to the flow direction of second cooling wind 39 in FIGS. 12 and 13 to facilitate understanding, the fin preferably extends in the flow direction of second cooling wind 39. This is the same in the following exemplary embodiments.

In a plate-separating heat exchanger, heat is transferred from high-temperature fluid to low-temperature fluid without causing mixing thereof when convective heat transfer occurs between the high-temperature fluid and the partition, heat conduction occurs inside the partition in the thickness direction thereof, and convective heat transfer occurs between the partition and the low-temperature fluid. Thus, when heat sink 41 according to the present exemplary embodiment is provided at a position illustrated in FIG. 12, convective heat transfer between a partition (wall of housing member 30) and low-temperature fluid (cooling wind 39) can be improved. With this configuration, the cooling performance of the sealed circulation cooling system can be further enhanced.

### Fourth Exemplary Embodiment

The following describes the fourth exemplary embodiment of the present invention with reference to FIG. 14. FIG. 14 is a pattern diagram illustrating a part corresponding to part A illustrated in FIG. 12 in the present exemplary embodiment.

Heat sink 41 is integrated with a body of housing member 30 (refer to FIGS. 12 and 13) in the third exemplary embodiment, but is provided as a member separated from housing member 30 in the present exemplary embodiment. More specific description of the present exemplary embodiment is given below.

Housing member 30 includes a housing member body 30a and a thermally conductive member 42 separated from housing member body 30a. Thermally conductive member 42 includes a fin and functions as a heat sink. Accordingly, for example, housing member body 30a can be formed of a light magnesium alloy, whereas only thermally conductive member 42 can be formed of an aluminum alloy, which is highly thermally conductive. Thus, reduction can be achieved in the weight of the optical engine.

In the present exemplary embodiment, since thermally conductive member 42 is separated from housing member body 30a as illustrated in FIG. 14, each fin of thermally conductive member 42 can extend outside housing member 30 as well as inside housing member 30.

The fin inside housing member 30 functions as a heat-receiving fin that receives the heat of first cooling wind 38b. This configuration improves convective heat transfer between a partition (thermally conductive member 42) and low-temperature fluid (second cooling wind 39) in a plate-separating heat exchanger, and also improves convective heat transfer between high-temperature fluid (second cooling wind 38b) and the partition (thermally conductive member 42). Accordingly, the cooling performance of the sealed circulation cooling system can be significantly enhanced.

Heat conduction inside the partition in the thickness direction thereof can be improved by the use of an aluminum alloy, which is highly thermally conductive.

### Fifth Exemplary Embodiment

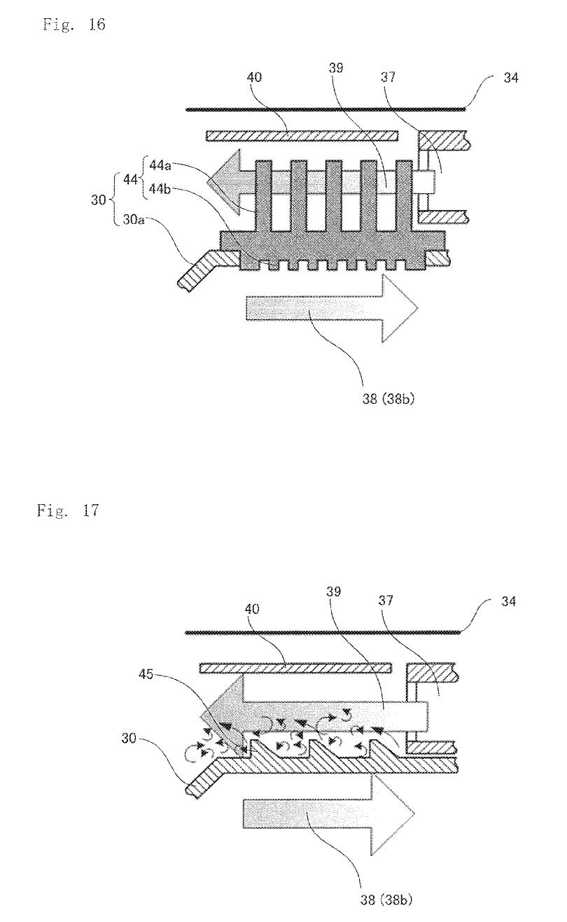

The following describes the fifth exemplary embodiment of the present invention with reference to FIG. 15. FIG. 15 is a pattern diagram illustrating a part corresponding to part A illustrated in FIG. 12 in the present exemplary embodiment.

Although thermally conductive member 42 functions as a heat sink including a fin in the fourth exemplary embodiment (refer to FIG. 14), a thermally conductive member 43 provides a micro channel in the present exemplary embodiment. Thermally conductive member 43 is used to achieve a counter-current micro channel heat exchanger.

The micro channel is defined as a narrow flow path fabricated by a fine fabrication technology or the like and typically has a diameter of several millimeters or less at which the effect of surface tension is applied. It is known that a typical heat exchanger has an in-pipe heat-transfer coefficient proportional to the reciprocal of the dimension of a flow-path section of a pipe, and thus the micro channel heat exchanger has a high heat-transfer coefficient.

The present exemplary embodiment is preferable, for example, when the fin cannot sufficiently extend inside housing member 30 or when the fin cannot sufficiently extend outside housing member 30. The fin cannot sufficiently extend inside housing member 30, for example, when the fin interferes with any optical component inside housing member 30. The fin cannot sufficiently extend outside housing member 30, for example, when there is restriction placed by housing 34.

Similarly to the fourth exemplary embodiment, when a heat exchange site (thermally conductive member 43) of housing member 30 is formed of a highly thermally conductive separate member (made of, for example, aluminum alloy), fine fabrication of the micro channel can be achieved on both surfaces. Accordingly, a small high-performance sealed circulation cooling system can be obtained.

### Sixth Exemplary Embodiment

The following describes the sixth exemplary embodiment of the present invention with reference to FIG. 16. FIG. 16 is a pattern diagram illustrating a part corresponding to part A illustrated in FIG. 12 in the present exemplary embodiment.

In the sixth exemplary embodiment of the present invention, housing member 30 includes housing member body 30a and thermally conductive member 44 separated from housing member body 30a. Thermally conductive member 44 includes, outside housing member 30, fin 44a corresponding to thermally conductive member 42 in the fourth exemplary embodiment, and includes, inside housing member 30, micro-channel formation part 44b corresponding to thermally conductive member 43 in the fifth exemplary embodiment.

The present exemplary embodiment is preferable when a sufficient space can be provided outside housing member 30 but no sufficient space can be provided inside housing member 30. In the present exemplary embodiment, similarly to the fourth and fifth exemplary embodiments, a small high-performance sealed circulation cooling system can be obtained.

### Seventh Exemplary Embodiment

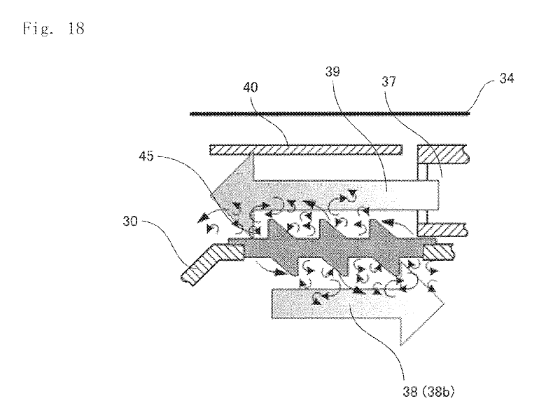

The following describes a seventh exemplary embodiment of the present invention with reference to FIG. 17. FIG. 17 is a pattern diagram illustrating a part corresponding to part A illustrated in FIG. 12 in the present exemplary embodiment. In the present exemplary embodiment, turbulence promoter 45 is formed at a heat exchange part (part that transfers the heat of first cooling wind 38b to second cooling wind 39) of housing member 30.

In a typical method for improving the heat-transfer performance of a heat exchanger, a turbulence promoting body is installed on a heat-transfer surface to improve a heat-transfer coefficient. The method exploits a property in which the heat-transfer coefficient increases as air flow changes from laminar flow to turbulent flow. The method is intended to achieve improved heat-transfer performance by installing the turbulence promoting body in a flow path to increase the heat-transfer coefficient near a re-adhesion point. This method is easily applicable and inexpensive, and thus highly usable.

Since turbulence promoter 45 is provided on the outer surface of housing member 30 to produce the turbulent flow of second cooling wind 39, the heat exchanger according to the present exemplary embodiment has a small size but achieves improved convective heat transfer between a partition (housing member 30) and low-temperature fluid (second cooling wind 39). With this configuration, the heat radiating performance of the sealed circulation cooling system can be further enhanced.

### Eighth Exemplary Embodiment

The following describes the eighth exemplary embodiment of the present invention with reference to FIG. 18. FIG. 18 is a pattern diagram illustrating a part corresponding to part A illustrated in FIG. 12 in the present exemplary embodiment.

In the present exemplary embodiment, housing member 30 includes housing member body 30a and thermally conductive member 46 formed separately from housing member body 30a. Thermally conductive member 46 includes a turbulence promoting body integrated with housing member 30 in the seventh exemplary embodiment.

When thermally conductive member 46 is formed separately from housing member body 30a, similarly to the fourth exemplary embodiment, reduction can be achieved in the weight of the optical engine, and turbulence promoting bodies can be provided outside and inside housing member 30. This configuration improves convective heat transfer between a partition (thermally conductive member 46) and low-temperature fluid (second cooling wind 39) in a plate-separating heat exchanger, and also improves convective heat transfer between high-temperature fluid (first cooling wind 38) and the partition (thermally conductive member 46). Accordingly, the heat exchanger according to the present exemplary embodiment has a small size but provides a sealed circulation cooling system having significantly improved cooling performance.

Since the first and second cooling winds 38 and 39 flow in opposite directions outside and inside housing member 30, the turbulence promoting bodies are designed to be oriented in opposite directions between the outside and inside of housing member 30.

Heat conduction inside the partition in the thickness direction thereof can be improved by the use of a highly thermally conductive material (such as an aluminum alloy).

Similarly to the sixth exemplary embodiment, configurations in different combinations (for example, a fin is formed outside housing member 30, and a turbulence promoting body is formed inside housing member 30) outside and inside housing member 30 are applicable in accordance with the optical engine and housing 34.

### REFERENCE SIGNS LIST

1 cooling device
2 housing member
3 heat transferring means
4 heat radiator
5 air blower
6 heat generating body
7 cooling device
8 heat absorber
9 air blower
10 projection display device
11 laser light source
12 fluorescent wheel
13 color wheel
14 light tunnel
15 DMD
16 projection lens
17 collimator lens
18 dichroic mirror
19 light condensing lens
20 reflection mirror
21 light condensing lens
22 light condensing lens
23 total internal reflection prism
24 fluorescent member
25 circular board
26 motor
27 color filter
28 circular board
29 motor
30 housing member
31 laser light
32 fluorescence
33 rectangular light beam
34 housing
35 cooling device
36 first air blower
37 second air blower
38 cooling wind
39 cooling wind
40 wind guiding plate
41 heat sink
42 thermally conductive member
43 thermally conductive member
44 thermally conductive member
45 turbulence promoter
46 thermally conductive member

1. A cooling device comprising:
a thermally conductive housing member that houses a heat generating body;
a first air blower that generates first cooling wind flowing inside said housing member; and
a second air blower that generates second cooling wind flowing outside said housing member.

2. The cooling device according to claim 1, wherein the first cooling wind flows along an inner wall of said housing member, and the first cooling wind flows along an outer wall of said housing member.

3. The cooling device according to claim 2, wherein the first cooling wind flowing along the inner wall of said housing member flows in a direction opposite to the direction of the second cooling wind flowing along the outer wall of said housing member.

4. The cooling device according to claim 2, further comprising a wind guiding plate that guides the second cooling wind along said housing member.

5. The cooling device according to claim 1, wherein said housing member includes a fin extending inside or outside of said housing member, or extending inside and outside of said housing member.

6. The cooling device according to claim 1, wherein said housing member includes a micro channel formed inside or outside of said housing member, or formed inside and outside of said housing member.

7. The cooling device according to claim 1, wherein said housing member includes a turbulence promoting body formed inside or outside of said housing member, or formed inside and outside of said housing member.

8. The cooling device according to claim 1, wherein said housing member includes a housing member body, and a thermally conductive member as a member separated from said housing member body.

9. A projection display device comprising the cooling device according to claim 1, wherein the heat generating body is an optical component.

10. The projection display device according to claim 9, wherein the optical component includes at least one device from among a fluorescent wheel, a color wheel, and a light tunnel.

11. A cooling method comprising:
housing a heat generating body in a thermally conductive housing member;
generating first cooling wind flowing inside the housing member; and
generating second cooling wind flowing outside the housing member.
